(19) United States
(12) Patent Application Publication
(10) Pub. No.: US 2026/0293062 A1
(43) Pub. Date: Sep. 24, 2026

(54) COOLING SYSTEM

(71) Applicant: MITSUBISHI HEAVY INDUSTRIES, LTD., Tokyo (JP)

(72) Inventors: Nobuhide Hara, Tokyo (JP); Yuichi Otani, Tokyo (JP); Yusuke Yamashina, Tokyo (JP); Takatada Saito, Tokyo (JP)

(73) Assignee: MITSUBISHI HEAVY INDUSTRIES, LTD., Tokyo (JP)

(21) Appl. No.: 19/473,637

(22) PCT Filed: Jan. 25, 2024
(86) PCT No.: PCT/JP2024/002214

§ 371 Date: Oct. 8, 2025

(30) Foreign Application Priority Data
Jun. 30, 2023 (JP) 2023-108617

(51) Int. Cl. H05K 7/20

(52) U.S. Cl. CPC H05K 7/20836; H05K 7/20154; H05K 7/20209; H05K 7/20281; H05K 7/20745; H05K 7/20772

(57) ABSTRACT

A cooling system includes: a cooling device that cools a heat medium; air conditioning means supplied with the heat medium to cool a room in which a load device is installed; a local cooling device supplied with the heat medium to cool the load device; and a heat medium loop that includes a first line through which the heat medium is circulated from the cooling device via the air conditioning means, and a second line that branches from the first line and through which the heat medium is circulated via the local cooling device. The first line has a smaller pressure loss than the second line.

### TECHNICAL FIELD

The present disclosure relates to a cooling system. This application claims priority of Japanese Patent Application No. 2023-108617 filed in Japan on Jun. 30, 2023, the contents of which are incorporated herein by reference.

### BACKGROUND ART

For example, there is provided a cooling system that includes a heat source device (chiller) that cools an indoor heat medium of a data center or the like in which a large number of load devices that generate heat, such as IT devices (servers), are installed, and an air conditioner that cools a room with the heat medium supplied from the heat source device (refer to PTLs 1 to 3).

### CITATION LIST

### Patent Literature

[PTL 1] Japanese Patent No. 6001375

[PTL 2] Japanese Patent No. 6125836

[PTL 3] Japanese Unexamined Patent Application Publication No. 2022-181304

### SUMMARY OF INVENTION

### TECHNICAL PROBLEM

In recent years, in addition to an air conditioner that cools a room, a cooling system may further include a local cooling device (chip cooling or the like) that cools a high heat generating body such as a CPU or a GPU of a load device. In the related art, it is necessary to provide both a heat source device for the air conditioner and a heat source device for the local cooling device and to individually control the air conditioner and the local cooling device. In this case, power is consumed by each device even in a standby state (idling state), and thus the power consumption of the entire cooling system increases.

An object of the present disclosure is to provide a cooling system that can cool both a room and a load device with a simple configuration and that can reduce power consumption.

### Solution to Problem

According to an aspect of the present disclosure, there is provided a cooling system including a cooling device that cools a heat medium, air conditioning means supplied with the heat medium to cool a room in which a load device is installed, a local cooling device supplied with the heat medium to cool the load device, and a heat medium loop that includes a first line through which the heat medium is circulated from the cooling device via the air conditioning means, and a second line that branches from the first line and through which the heat medium is circulated via the local cooling device, in which the first line has a smaller pressure loss than the second line.

### Advantageous Effects of Invention

According to the above aspect, both the room and the load device can be cooled with a simple configuration, and the power consumption can be reduced.

### BRIEF DESCRIPTION OF DRAWINGS

FIG. 1 is a diagram showing an overall configuration of a cooling system according to a first embodiment.

FIG. 2 is a diagram showing a functional configuration of a control device according to the first embodiment.

FIG. 3 is a flowchart showing an example of processing of the control device according to the first embodiment.

FIG. 4 is a diagram showing an example of a control command value of the control device according to the first embodiment.

FIG. 5 is a diagram showing an overall configuration of a cooling system according to a second embodiment.

FIG. 6 is a diagram showing an example of a control command value of the control device according to the second embodiment.

FIG. 7 is a diagram showing an overall configuration of a cooling system according to a third embodiment.

FIG. 8 is a diagram showing an overall configuration of a cooling system according to a fourth embodiment.

FIG. 9 is a diagram showing a configuration of a second line and a local cooling device according to a fifth embodiment.

### DESCRIPTION OF EMBODIMENTS

### FIRST EMBODIMENT

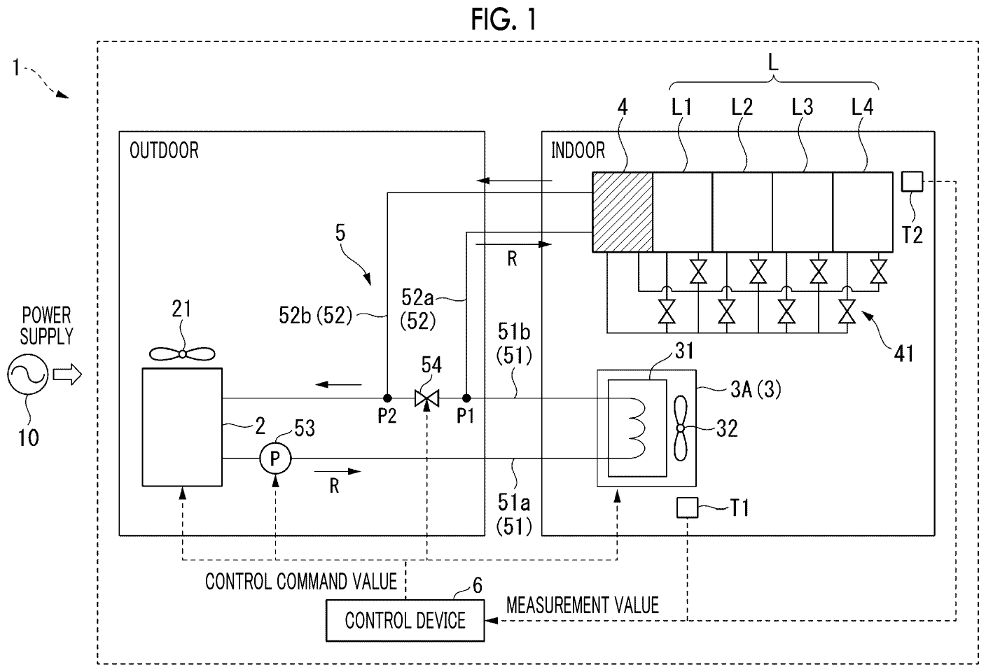

Hereinafter, a first embodiment will be described in detail with reference to FIGS. 1 to 4.

### Overall Configuration of Cooling System

FIG. 1 is a diagram showing an overall configuration of a cooling system according to the first embodiment.

As shown in FIG. 1, a cooling system 1 is a system for cooling a room of a facility (server room, data center, or the like) in which a plurality of load devices L (L1, L2, L3, LA, . . . ) are installed, as well as the load devices L. The load device L is, for example, a device having a heat generating body (CPU, GPU, or the like) such as a server or a communication device.

The cooling system 1 includes a cooling device 2, air conditioning means 3, a local cooling device 4, a heat medium loop 5, a control device 6, and a power supply 10.

The cooling device 2 is, for example, an air-cooled chiller or a cooling tower of a free cooling type, and is installed outdoors. The cooling device 2 includes a fan 21. The cooling device 2 takes in low temperature outside air with the fan 21 and cools a heat medium R supplied to the air conditioning means 3 and the local cooling device 4. The heat medium R may be any form, such as brine, for example.

The air conditioning means 3 is an air conditioner 3A that cools indoor air. The air conditioner 3A includes a heat exchanger 31 and an air conditioner fan 32. The heat exchanger 31 exchanges heat between the heat medium R cooled by the cooling device 2 and the indoor air warmed by the load device L. The air conditioner fan 32 blows out air cooled by the heat exchanger 31 into the room. In FIG. 1, an example in which only one air conditioning means 3 is provided in the room is shown, but the present disclosure is not limited thereto. In another embodiment, a plurality of the air conditioning means 3 may be provided in the room.

The local cooling device 4 is a chip cooling device that cools each of the plurality of load devices L. The local cooling device 4 includes a local cooling loop 41. The local cooling loop 41 takes in the heat medium R cooled by the cooling device 2 from the heat medium loop 5, distributes the heat medium R to each load device L, and also returns the heat medium R discharged from each load device L to the heat medium loop 5. The heat medium R distributed and supplied to each load device L cools the load device L by absorbing heat from the heat generating body of the load device L.

The heat medium loop 5 includes a first line 51 and a second line 52. The first line 51 is a flow path through which the heat medium R is circulated via the air conditioner 3A. The second line 52 is a flow path that branches from the first line 51 and through which the heat medium R is circulated via the local cooling device 4. In addition, the first line 51 is provided with a pump 53, and the pump 53 draws in the heat medium R cooled by the cooling device 2 and delivers the heat medium R to a downstream side (air conditioner 3A side) of the first line 51.

The first line 51 has a first low temperature line 51a that supplies the heat medium R to the air conditioner 3A, and a first high temperature line 51b that allows the heat medium R, which has completed heat exchange in the heat exchanger 31 of the air conditioner 3A, to flow downstream. The second line 52 has a second low temperature line 52a that supplies the heat medium R to the local cooling device 4, and a second high temperature line 52b that allows the heat medium R, which has been warmed by the heat generating body of the load device L, to flow to the downstream side. The second line 52 according to the present embodiment is connected in series with the first line 51. The second low temperature line 52a of the second line 52 branches from the first high temperature line 51b of the first line 51 at a branching point P1. Thereafter, the second high temperature line 52b of the second line 52 merges with the first high temperature line 51b of the first line 51 at a merging point P2 on a downstream side of the branching point P1. Normally, the heat generating body of the load device L has a higher temperature than the indoor temperature. Therefore, even in a case where the heat medium R after being heat-exchanged by the heat exchanger 31 of the air conditioner 3A is reused, the local cooling device 4 can sufficiently absorb heat from the heat generating body of the load device L. For this reason, the heat medium R used in the air conditioner 3A is further used in the local cooling device 4 on the downstream side. In this manner, it is not necessary to provide a plurality of cooling devices 2 for each of the air conditioner 3A and the local cooling device 4, and the heat medium R cooled by one cooling device 2 can be used to the maximum extent.

As described above, the second line 52 according to the present embodiment has the local cooling loop 41 in which the local cooling device 4 is branched into a plurality of flow paths. In addition, the local cooling loop 41 uses a pipe having a smaller diameter than a pipe of the first line 51. By making the diameters of the pipes different in this way, a pressure loss becomes unbalanced between the first line 51 and the second line 52. That is, the first line 51 is designed to have a smaller pressure loss than the second line 52. A flow rate of the heat medium R bypassing from the first line 51 to the second line 52 can be regulated by regulating a difference in pressure loss between the first line 51 and the second line 52 by adjusting a difference in the diameter of the pipe or the like. In addition, as long as the pressure loss of the first line 51 and the second line 52 can be made unbalanced, the second line 52 may have various other configurations without being limited to the configuration in which the local cooling loop 41 described above has a small diameter. For example, in another embodiment, instead of the local cooling loop 41 or in addition to the local cooling loop 41, the diameter of at least one pipe of the second low temperature line 52a and the second high temperature line 52b of the second line 52 may be smaller than the diameter of the pipe of the first line 51. In still another embodiment, a length of the pipe of the second line 52 (local cooling loop 41, second low temperature line 52a, and second high temperature line 52b) may be longer than that of the first line 51, or the pipe may be bent more than the first line 51, so that a pressure loss greater than that of the first line 51 may occur in the second line 52.

In addition, as means for further adjusting the flow rate of the heat medium R bypassing to the second line 52, in the present embodiment, an adjustment valve 54 is provided in the first line 51 having a small pressure loss. In the present embodiment, the adjustment valve 54 is provided between the branching point P1 and the merging point P2 of the first line 51.

An opening degree of the adjustment valve 54 may be two values of maximum (for example, fully open) or minimum (for example, fully closed), or may be adjustable to any value in a range from the maximum to the minimum. Since the pressure loss of the first line 51 is smaller than that of the second line 52 and the heat medium R is likely to flow, the flow rate of the heat medium R flowing to the downstream side of the first line 51 (first high temperature line 51b) increases as the opening degree of the adjustment valve 54 increases. Accordingly, the flow rate of the heat medium R bypassing from the branching point P1 of the first line 51 to the second line 52 decreases. In a case where the opening degree of the adjustment valve 54 is at its maximum, only the heat medium R having the minimum flow rate corresponding to the difference in pressure loss bypasses to the second line 52. On the other hand, as the opening degree of the adjustment valve 54 decreases, the flow rate of the heat medium R flowing to the downstream side of the first line 51 (first high temperature line 51b) decreases. Accordingly, the flow rate of the heat medium R bypassing to the second line 52 from the branching point P1 of the first line 51 increases. That is, the flow rates of the first line 51 and the second line 52 can be adjusted by opening and closing the adjustment valve 54.

The control device 6 outputs a control signal for controlling operations of the cooling device 2, the air conditioner 3A, the pump 53, and the adjustment valve 54. The control device 6 may be installed in the same room as the air conditioner 3A or the local cooling device 4, or may be installed in another room or the like within the facility. In addition, the control device 6 may be built in the cooling device 2. A detailed functional configuration of the control device 6 will be described later.

The power supply 10 supplies power for operating each unit of the cooling system 1. The power supply 10 is, for example, a power system. In another embodiment, the power supply 10 may be a power generation device that uses natural energy (a solar power generation device, a wind power generation device, a hydroelectric power generation device, a geothermal power generation device, or the like).

### Functional Configuration of Control Device

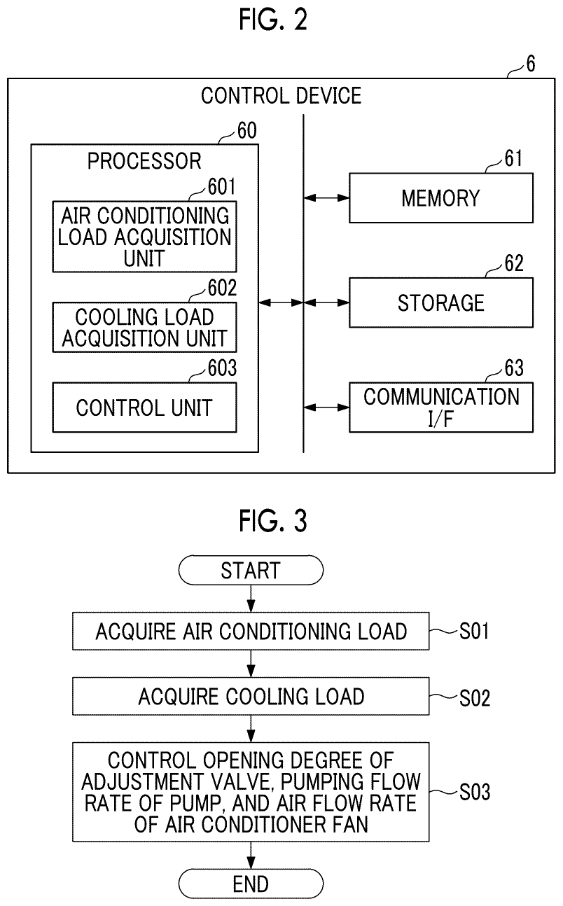

FIG. 2 is a diagram showing a functional configuration of the control device according to the first embodiment.

As shown in FIG. 2, the control device 6 includes a processor 60, a memory 61, a storage 62, and a communication interface (1/F) 63.

The processor 60 operates according to a predetermined program to perform functions of an air conditioning load acquisition unit 601, a cooling load acquisition unit 602, and a control unit 603.

The air conditioning load acquisition unit 601 acquires an air conditioning load of the air conditioner 3A based on a temperature in the room (indoor temperature) where the air conditioner 3A is installed. For example, as shown in FIG. 1, the indoor temperature is measured by a first temperature sensor T1 installed in the vicinity of the air conditioner 3A.

The cooling load acquisition unit 602 acquires a load of the local cooling device 4 (cooling load) based on a temperature of the load device L or a temperature of the second line 52. For example, as shown in FIG. 1, a second temperature sensor T2 is installed in the vicinity of the load device L in the room (server rack or the like), and the temperature of the load device L is measured. In addition, in another embodiment, the second temperature sensor T2 may be provided at each of an inlet (second low temperature line 52a) and an outlet (second high temperature line 52b) of the local cooling device 4, and the temperature of the second line 52 may be measured.

The control unit 603 controls the opening degree of the adjustment valve 54 based on the air conditioning load and the cooling load. In addition, the control unit 603 may control the pump 53 or the air conditioner fan 32 of the air conditioner 3A based on the air conditioning load and the cooling load.

The predetermined program executed by the processor 60 is stored in a computer-readable recording medium. In addition, examples of the computer-readable recording medium include a magnetic disk, a magneto-optical disk, a CD-ROM, a DVD-ROM, and a semiconductor memory. In addition, the computer program may be distributed to a computer via a communication line, and the computer receiving the distribution may execute the program. Further, the program may be a program for realizing some of the functions described above. Further, the program may be a so-called difference file (difference program) that can realize the functions described above in combination with a program already recorded in a computer system.

The memory 61 has a memory area necessary for an operation of the processor 60.

The storage 62 is a so-called auxiliary storage device and is, for example, a hard disk drive (HDD), a solid-state drive (SSD), or the like. The storage 62 stores data that is acquired, generated, and referred to by each unit of the processor 60 during processing.

The communication I/F 63 transmits and receives signals (such as control command values and measurement values) to and from each device.

### Processing Flow of Control Device

FIG. 3 is a flowchart showing an example of processing of the control device according to the first embodiment.

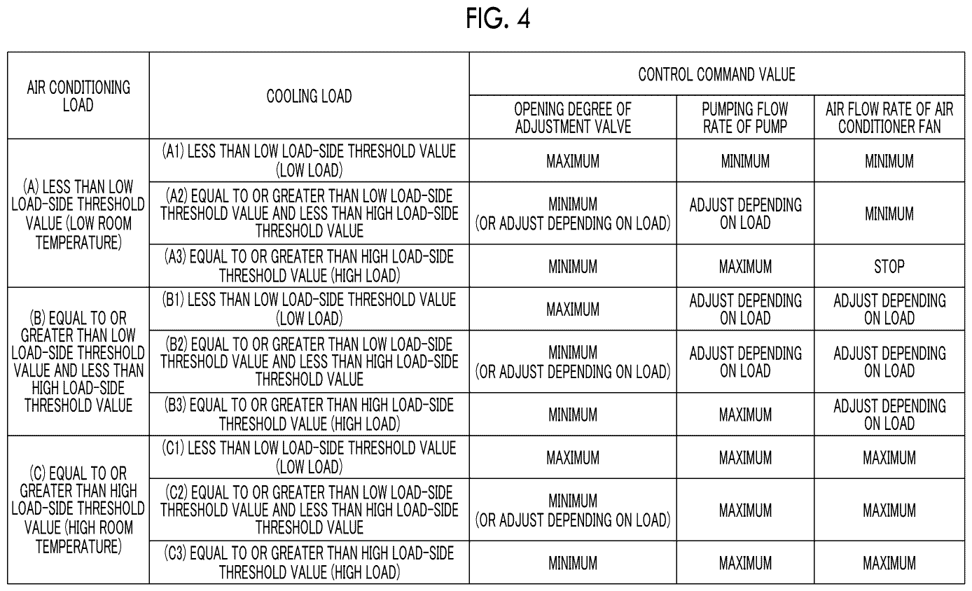

FIG. 4 is a diagram showing an example of a control command value of the control device according to the first embodiment.

Hereinafter, a processing flow of the control device 6 will be described with reference to FIGS. 3 and 4.

First, the air conditioning load acquisition unit 601 acquires the air conditioning load of the air conditioner 3A (Step S01). For example, the air conditioning load according to the present embodiment is an indoor temperature measured by the first temperature sensor T1.

Next, the cooling load acquisition unit 602 acquires the cooling load of the local cooling device 4 (Step S02). For example, the cooling load according to the present embodiment is a temperature of the load device L measured by the second temperature sensor T2.

In another embodiment, the cooling load may be, for example, a rate of increase in temperature of the load device L per unit time or a difference between the temperature of the load device L and the indoor temperature. In addition, in still another embodiment, the cooling load may be a temperature difference of the heat medium R at the inlet and outlet of the local cooling device 4, a rate of increase in the temperature difference of the heat medium R per unit time, or the like.

Next, the control unit 603 controls the opening degree of the adjustment valve 54, a pumping flow rate of the heat medium R of the pump 53, and the air flow rate of the air conditioner fan 32 of the air conditioner 3A based on the air conditioning load and the cooling load (Step S03).

Specifically, the control unit 603 determines the control command value of each unit according to the combination (load state) of the air conditioning load and the cooling load as shown in FIG. 4.

### (A1) Low Room Temperature and Low Load

In a case where the air conditioning load is less than an air conditioning low load-side threshold value (low room temperature) and the cooling load is less than a cooling low load-side threshold value (low load), the control unit 603 increases the opening degree of the adjustment valve 54. In addition, in this case, the control unit 603 reduces the pumping flow rate of the pump 53 and reduces the air flow rate of the air conditioner fan 32. For example, the control unit 603 adjusts the opening degree of the adjustment valve 54 to be larger as the cooling load decreases, and adjusts the pumping flow rate of the pump 53 and the air flow rate of the air conditioner fan 32 to be smaller. In addition, as shown in FIG. 4, the opening degree of the adjustment valve 54 may be set to the maximum, the pumping flow rate of the pump 53 may be set to the minimum, and the air flow rate of the air conditioner fan 32 may be set to the minimum. In this way, it is possible to reduce the pressure loss of the entire cooling system 1 and also reduce the power consumption of the entire cooling system 1.

### (A2) Low Room Temperature and Medium Load

In a case where the air conditioning load is less than the air conditioning low load-side threshold value (low room temperature), and the cooling load is equal to or greater than the cooling low load-side threshold value and less than a cooling high load-side threshold value (medium load), the control unit 603 increases the flow rate of the heat medium R bypassing to the second line 52 by reducing the opening degree of the adjustment valve 54. For example, when the opening degree of the adjustment valve 54 is two values of maximum or minimum, the control unit 603 sets the opening degree of the adjustment valve 54 to the minimum. In a case where the opening degree of the adjustment valve 54 can be adjusted to any value, the control unit 603 may adjust the opening degree such that the opening degree of the adjustment valve 54 decreases as the cooling load increases. In addition, the control unit 603 adjusts the pumping flow rate of the pump to be larger as the cooling load increases. However, the control unit 603 does not increase the air flow rate of the air conditioner fan 32. In addition, as shown in FIG. 4, the air flow rate of the air conditioner fan 32 may be minimized. Accordingly, it is possible to increase or decrease the cooling capacity of the local cooling device 4 according to the cooling load while suppressing an increase in the cooling capacity and the power consumption of the air conditioner 3A.

### (A3) Low Room Temperature and High Load

In a case where the air conditioning load is less than the air conditioning low load-side threshold value (low room temperature) and the cooling load is equal to or greater than the cooling high load-side threshold value (high load), the control unit 603 decreases the opening degree of the adjustment valve 54 as the cooling load increases. In this way, the control unit 603 reduces a difference in pressure loss between the first line 51 and the second line 52 to increase the flow rate of the heat medium R bypassing to the second line 52. In addition, the control unit 603 increases the pumping flow rate of the pump and decreases the air flow rate of the air conditioner fan 32. In addition, as shown in FIG. 4, the opening degree of the adjustment valve 54 may be minimized, the pumping flow rate of the pump 53 may be maximized, and the air conditioner fan 32 may be stopped. In this manner, it is possible to reduce the consumption of power in the air conditioner 3A. In addition, by reducing the flow rate of the heat medium R used in the air conditioner 3A, the cooling capacity of the local cooling device 4 can be increased.

### (B1) Medium Room Temperature and Low Load

In a case where the air conditioning load is equal to or greater than the air conditioning low load-side threshold value and is less than the air conditioning high load-side threshold value (medium room temperature) and the cooling load is less than the cooling low load-side threshold value (low load), the control unit 603 increases the opening degree of the adjustment valve 54. For example, the control unit 603 may adjust the opening degree of the adjustment valve 54 to be larger as the cooling load decreases, or the opening degree of the adjustment valve 54 may be set to the maximum as in the example of FIG. 4. In addition, in this case, the control unit 603 adjusts the control command value such that the pumping flow rate of the pump 53 and the air flow rate of the air conditioner fan 32 increase as the air conditioning load increases. Accordingly, the pressure loss of the entire cooling system 1 can be reduced, and the load on the pump 53 can be reduced by reducing the flow rate of the heat medium R to the local cooling device 4. In addition, the cooling capacity and the power consumption of the air conditioner 3A can be appropriately adjusted according to the indoor temperature.

### (B2) Medium Room Temperature and Medium Load

In a case where the air conditioning load is equal to or greater than the air conditioning low load-side threshold value and is less than the air conditioning high load-side threshold value (medium room temperature), and the cooling load is equal to or greater than the cooling low load-side threshold value and less than the cooling high load-side threshold value (medium load), the control unit 603 increases the flow rate of the heat medium R bypassing to the second line 52 by reducing the opening degree of the adjustment valve 54. For example, when the opening degree of the adjustment valve 54 is two values of maximum or minimum, the control unit 603 sets the opening degree of the adjustment valve 54 to the minimum. In a case where the opening degree of the adjustment valve 54 can be adjusted to any value, the control unit 603 may adjust the opening degree such that the opening degree of the adjustment valve 54 decreases as the cooling load increases. In addition, the control unit 603 adjusts the pumping flow rate of the pump to be larger as the air conditioning load or the cooling load increases, and also adjusts the air flow rate of the air conditioner fan 32 to be larger as the air conditioning load increases. Accordingly, it is possible to appropriately adjust the cooling capacities of the air conditioner 3A and the local cooling device 4 while reducing the power used in the entire cooling system 1.

### (B3) Medium Room Temperature and High Load

In a case where the air conditioning load is equal to or greater than the air conditioning low load-side threshold value and less than the air conditioning high load-side threshold value (medium room temperature) and the cooling load is equal to or greater than the cooling high load-side threshold value (high load), the control unit 603 reduces the opening degree of the adjustment valve 54 to reduce the difference in pressure loss between the first line 51 and the second line 52 and to increase the flow rate of the heat medium R bypassing to the second line 52. In addition, the control unit 603 adjusts the pumping flow rate of the pump 53 and the air flow rate of the air conditioner fan 32 to be larger as the air conditioning load increases. In addition, as shown in FIG. 4, the opening degree of the adjustment valve 54 may be minimized and the pumping flow rate of the pump 53 may be maximized. Accordingly, the cooling capacity of the local cooling device 4 can be increased, and the cooling capacities of the air conditioner 3A and the local cooling device 4 can be appropriately adjusted.

### (C1) High Room Temperature and Low Load

In a case where the air conditioning load is equal to or greater than the air conditioning high load-side threshold value (high room temperature) and the cooling load is less than the cooling low load-side threshold value (low load), the control unit 603 increases the opening degree of the adjustment valve 54. For example, the control unit 603 adjusts the opening degree of the adjustment valve 54 to be larger as the cooling load decreases. In addition, the control unit 603 increases the pumping flow rate of the pump 53 and increases the air flow rate of the air conditioner fan 32. In addition, as shown in FIG. 4, the opening degree of the adjustment valve 54 may be set to the maximum. Accordingly, the pressure loss of the entire cooling system 1 can be reduced, and the load on the pump 53 can be reduced by reducing the flow rate of the heat medium R to the local cooling device 4. In addition, the cooling capacity of the air conditioner 3A can be increased.

### (C2) High Room Temperature and Medium Load

In a case where the air conditioning load is equal to or greater than the air conditioning high load-side threshold value (high room temperature), and the cooling load is equal to or greater than the cooling low load-side threshold value and less than the cooling high load-side threshold value (medium load), the control unit 603 increases the flow rate of the heat medium R bypassing to the second line 52 by reducing the opening degree of the adjustment valve 54. For example, when the opening degree of the adjustment valve 54 is two values of maximum or minimum, the control unit 603 sets the opening degree of the adjustment valve 54 to the minimum. In a case where the opening degree of the adjustment valve 54 can be adjusted to any value, the control unit 603 may adjust the opening degree such that the opening degree of the adjustment valve 54 decreases as the cooling load increases. In addition, the control unit 603 increases the pumping flow rate of the pump 53 and increases the air flow rate of the air conditioner fan 32. As shown in FIG. 4, the pumping flow rate of the pump 53 and the air flow rate of the air conditioner fan 32 may be set to the maximum. Accordingly, the cooling capacity of the air conditioner 3A can be increased, and the cooling capacity of the local cooling device 4 can be also appropriately adjusted.

### (C3) High Room Temperature and High Load

In a case where the air conditioning load is equal to or greater than the air conditioning high load-side threshold value (high room temperature) and the cooling load is equal to or greater than the cooling high load-side threshold value (high load), the control unit 603 reduces the opening degree of the adjustment valve 54 to reduce the difference in pressure loss between the first line 51 and the second line 52 and to increase the flow rate of the heat medium R bypassing to the second line 52. In addition, the control unit 603 increases the pumping flow rate of the pump 53 and increases the air flow rate of the air conditioner fan 32. In addition, as shown in FIG. 4, the opening degree of the adjustment valve 54 may be minimized, and the pumping flow rate of the pump 53 and the air flow rate of the air conditioner fan 32 may be maximized. Accordingly, the cooling capacities of the air conditioner 3A and the local cooling device 4 can be increased.

The control device 6 can appropriately control the adjustment of the power consumption of the entire cooling system 1 and the cooling capacities of the air conditioner 3A and the local cooling device 4 by executing a series of processing in FIG. 3 at predetermined intervals during the operation of the cooling system 1.

### Operations and Effects

As described above, the cooling system 1 according to the present embodiment includes the cooling device 2 that cools the heat medium R, the air conditioning means (air conditioner 3A) supplied with the heat medium R to cool the room in which the load device L is installed, the local cooling device 4 supplied with the heat medium R to cool the load device L, and the heat medium loop 5 that includes the first line 51 through which the heat medium R is circulated from the cooling device 2 via the air conditioner 3A, and the second line 52 that branches from the first line 51 and through which the heat medium R is circulated via the local cooling device 4. The first line 51 has a smaller pressure loss than the second line 52.

Normally, the heat generating body of the load device L has a higher temperature than the indoor temperature. Therefore, even in a case where the heat medium R after being heat-exchanged by the heat exchanger 31 of the air conditioner 3A is reused, the local cooling device 4 can sufficiently absorb heat from the heat generating body of the load device L. For this reason, the heat medium R used in the air conditioner 3A is further used in the local cooling device 4 on the downstream side. In this manner, it is not necessary to provide a plurality of cooling devices 2 for each of the air conditioner 3A and the local cooling device 4, and the heat medium R cooled by one cooling device 2 can be used to the maximum extent. That is, both the room and the load device L can be cooled with a simple configuration in which only one cooling device 2 is installed, and the power consumption in the entire cooling system 1 can be reduced. Further, the flow rate of the heat medium R bypassing from the first line 51 to the second line 52 can be adjusted by adjusting the difference in pressure loss by adjusting a difference in the diameter of the pipe used in the first line 51 and the second line 52 according to the number of load devices L, the load (the amount of heat generated), or the like. That is, the cooling system 1 has a simple configuration in which the first line 51 and the second line 52 having different pressure losses are provided, and is capable of adjusting the flow rate and cooling capacity of the heat medium R supplied from one cooling device 2 to the air conditioner 3A and the local cooling device 4.

In addition, the first line 51 is provided with an adjustment valve 54 capable of adjusting the flow rate of the heat medium R in the first line 51 and the second line 52.

In this way, the cooling system 1 can adjust the flow rates of the first line 51 and the second line 52 by opening and closing the adjustment valve 54 and can adjust the cooling capacities of the air conditioner 3A and the local cooling device 4.

In addition, the cooling system 1 further includes the air conditioning load acquisition unit 601 that acquires the air conditioning load of the air conditioner 3A based on an indoor temperature, the cooling load acquisition unit 602 that acquires the cooling load of the local cooling device 4 based on a temperature of the load device L or a temperature of the second line 52, and the control unit 603 that controls an opening degree of the adjustment valve 54 based on the air conditioning load and the cooling load.

In this way, the cooling system 1 can appropriately adjust the flow rate of the heat medium R bypassing to the second line 52 according to the air conditioning load required for cooling the room by the air conditioner 3A or the cooling load required for cooling the load device L by the local cooling device 4.

In addition, the control unit 603 reduces the opening degree of the adjustment valve 54 in a case where the air conditioning load is less than the air conditioning low load-side threshold value (low room temperature) and the cooling load is equal to or greater than the cooling high load-side threshold value (high load).

In this way, the cooling system 1 can increase the flow rate of the heat medium R bypassing to the second line 52 and increase the cooling capacity of the local cooling device 4.

The control unit 603 increases the opening degree of the adjustment valve 54 in a case where the air conditioning load is equal to or greater than the air conditioning high load-side threshold value (high room temperature) and the cooling load is less than the cooling low load-side threshold value (low load).

In this way, the cooling system 1 can reduce the pressure loss of the entire system and increase the cooling capacity of the air conditioner 3A.

In addition, the air conditioning means is the air conditioner 3A having the air conditioner fan 32, and the control unit 603 stops the air conditioner fan 32 in a case where the air conditioning load is less than the air conditioning low load-side threshold value (low room temperature) and the cooling load is equal to or greater than the cooling high load-side threshold value (high load).

In this way, the cooling system 1 can minimize the consumption of power in the air conditioner 3A in a case where cooling of the room is not required.

### SECOND EMBODIMENT

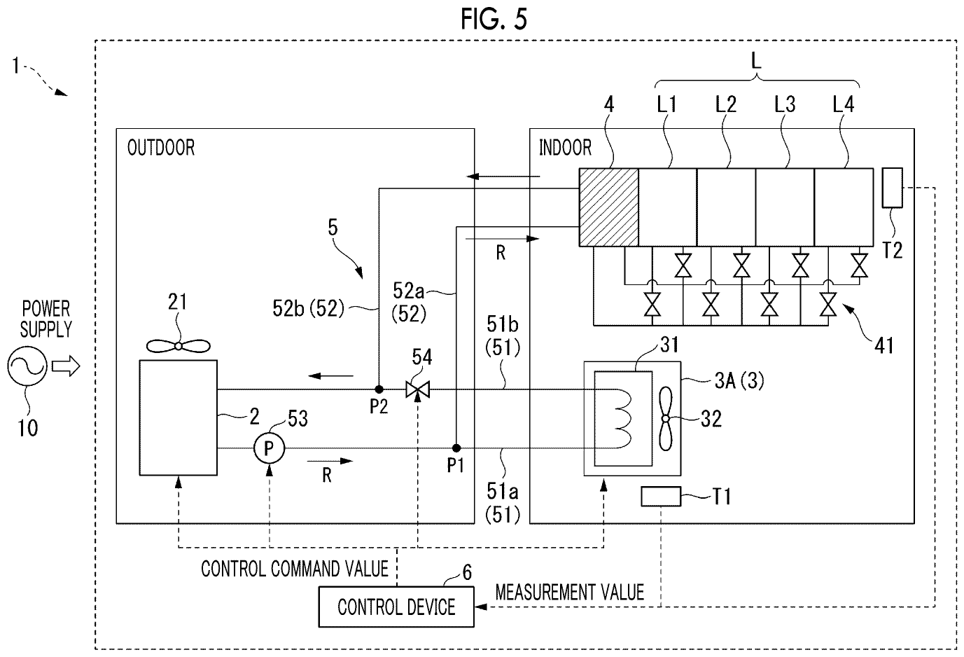

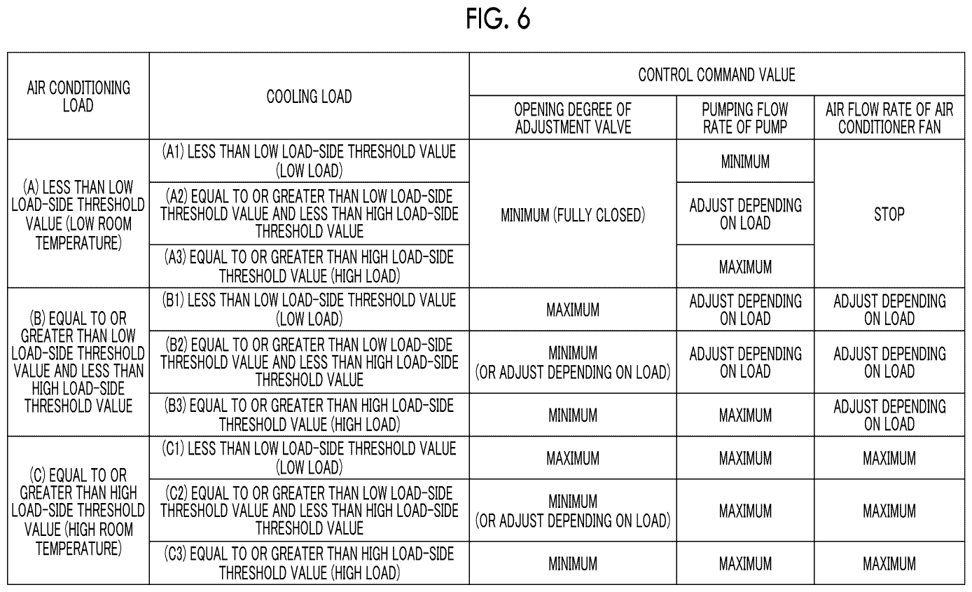

Next, a second embodiment will be described with reference to FIGS. 5 and 6. The same components as those in the above-described embodiment are denoted by the same reference numerals, and a detailed description thereof will be omitted.

FIG. 5 is a diagram showing an overall configuration of a cooling system according to the second embodiment.

In the first embodiment, the example in which the heat medium loop 5 has the first line 51 and the second line 52 directly connected thereto has been described. In contrast, in the second embodiment, an example in which the heat medium loop 5 has the first line 51 and the second line 52 connected in parallel will be described.

As shown in FIG. 5, the second low temperature line 52a of the second line 52 branches from the first low temperature line 51a of the first line 51 at the branching point P1. Thereafter, the second high temperature line 52b of the second line 52 merges with the first high temperature line 51b of the first line 51 at the merging point P2.

The adjustment valve 54 is provided between the branching point P1 and the merging point P2, as in the first embodiment. In addition, in a case where the adjustment valve 54 is fully closed, the heat medium R stops circulating in the first line 51 and circulates only in the second line 52. That is, all the heat medium R is supplied to the local cooling device 4.

FIG. 6 is a diagram showing an example of a control command value of the control device according to the second embodiment.

In addition, the control unit 603 of the control device 6 according to the present embodiment determines a control command value as shown in FIG. 6 instead of FIG. 4.

As shown in (A1) to (A3) of FIG. 6, in a case where the air conditioning load is less than the air conditioning low load-side threshold value (low room temperature), the control unit 603 sets the opening degree of the adjustment valve 54 to its minimum (fully closed). In addition, the control unit 603 stops the air conditioner fan 32.

In this way, in a case where cooling of the room is not required, for example, in winter, the cooling system 1 can supply the heat medium R only to the local cooling device 4 without supplying the heat medium R to the air conditioner 3A. As a result, it is not necessary to flow the heat medium R to an unnecessary location (air conditioner 3A), and thus the power consumption of the pump 53 or the like can be reduced. In addition, the power consumption can be further reduced by stopping the air conditioner fan 32. In addition, since the heat medium R that is cooled by the cooling device 2 is directly supplied to the local cooling device 4, the cooling capacity of the local cooling device 4 can be greatly improved as compared with the first embodiment.

### THIRD EMBODIMENT

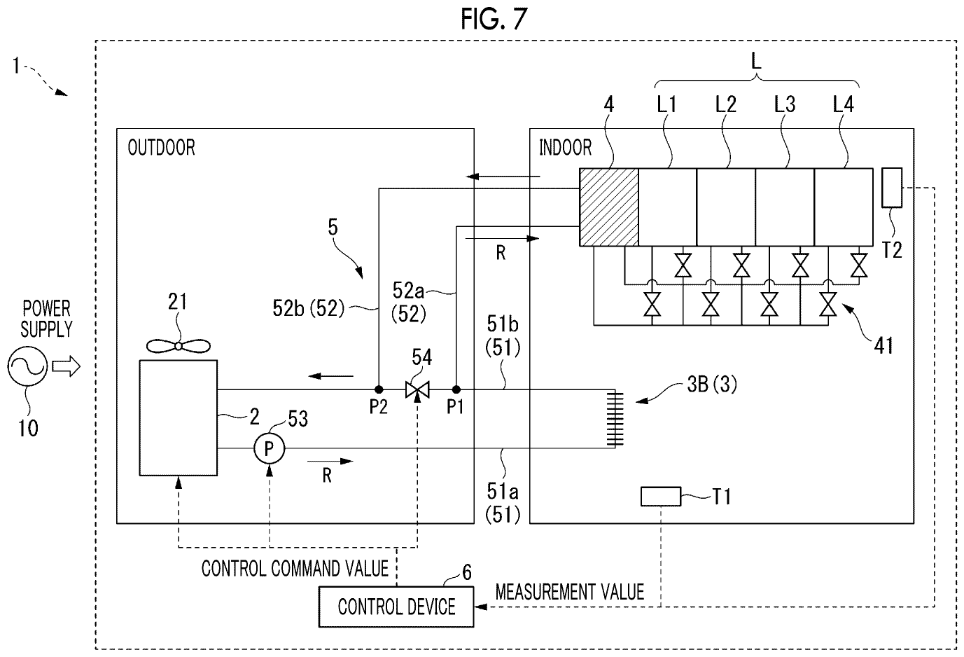

Next, a third embodiment will be described with reference to FIG. 7. The same components as those in the above-described embodiment are denoted by the same reference numerals, and a detailed description thereof will be omitted.

FIG. 7 is a diagram showing an overall configuration of a cooling system according to the third embodiment.

As shown in FIG. 7, the air conditioning means 3 according to the present embodiment is a finned tube 3B.

FIG. 7 shows an example in which the air conditioner 3A in the first embodiment is replaced with the finned tube 3B, but the present disclosure is not limited thereto. In another embodiment, the air conditioner 3A in the second embodiment (FIG. 5) may be replaced with the finned tube 3B.

In addition, the control unit 603 of the control device 6 according to the present embodiment does not perform the processing of determining the control command value of the air conditioner fan 32 shown in FIGS. 4 and 6.

For example, in a facility provided in a high latitude region, an indoor temperature may be low throughout the year. As a result, it is assumed that a device having high cooling capacity, such as the air conditioner 3A, is not required. In this case, by replacing the air conditioning means 3 from the air conditioner 3A with the finned tube 3B, the power consumption of the cooling system 1 can be significantly reduced while ensuring the cooling capacity of the room with the flow rate of the heat medium R flowing through the finned tube 3B.

### FOURTH EMBODIMENT

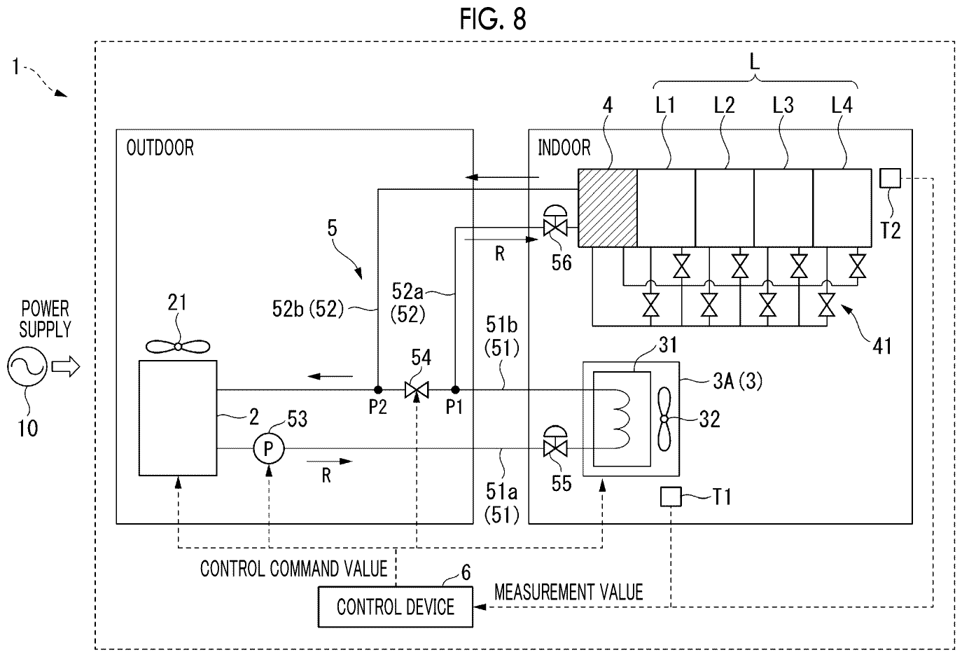

Next, a fourth embodiment will be described with reference to FIG. 8. The same components as those in the above-described embodiment are denoted by the same reference numerals, and a detailed description thereof will be omitted.

FIG. 8 is a diagram showing an overall configuration of a cooling system according to the fourth embodiment.

In the fourth embodiment, the opening degree of the adjustment valve 54 is two values of maximum (fully open) or minimum (fully closed). In addition, as shown in FIG. 8, the first line 51 is provided with a first valve 55 capable of adjusting the flow rate of the heat medium R flowing through the first line 51 (supplied to the air conditioning means 3). The second line 52 is provided with a second valve 56 capable of adjusting the flow rate of the heat medium R flowing through the second line 52 (supplied to the local cooling device 4).

In addition, although FIG. 8 shows an example in which the first valve 55 and the second valve 56 are added to the configuration of the first embodiment, the present disclosure is not limited thereto. In another embodiment, the first valve 55 and the second valve 56 may be added to the configuration of the second embodiment (FIG. 5) or the third embodiment (FIG. 7).

In addition, in a case of (A2), (B2), and (C2) in FIG. 4 or in a case of (B2) and (C2) in FIG. 6, the control unit 603 of the control device 6 adjusts the opening degrees of the first valve 55 and the second valve 56 according to the air conditioning load and the cooling load while minimizing the opening degree of the adjustment valve 54.

In this way, the cooling system 1 can finely adjust the flow rate of the heat medium R in the first line 51 and the second line 52 while maintaining a simple configuration of the adjustment valve 54.

### FIFTH EMBODIMENT

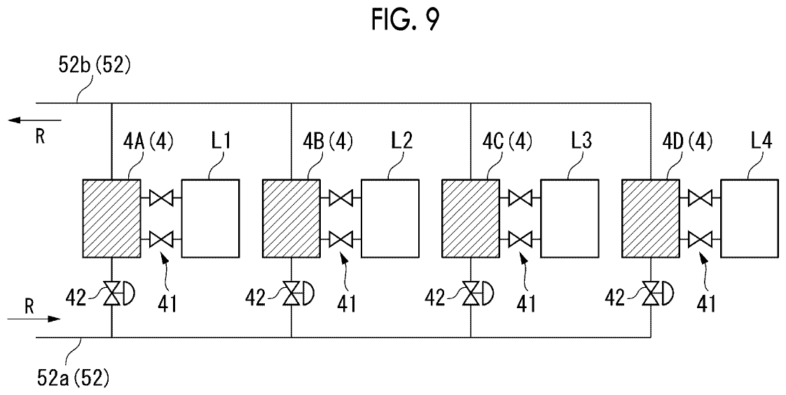

Next, a fifth embodiment will be described with reference to FIG. 9. The same components as those in the above-described embodiment are denoted by the same reference numerals, and a detailed description thereof will be omitted.

FIG. 9 is a diagram showing a configuration of a second line and a local cooling device according to the fifth embodiment.

As shown in FIG. 9, one local cooling device 4 may be provided for each load device L. FIG. 9 shows an example in which one local cooling device 4A to 4D is provided for each of the four load devices L1 to L4.

In addition, the second low temperature line 52a of the second line 52 is branched and connected to each local cooling device 4 (4A to 4D). In addition, local cooling valves 42 (42A to 42D) are provided in the respective branch paths to each of the local cooling devices 4 of the second low temperature line 52a. The local cooling valve 42 adjusts the flow rate of the heat medium R supplied from the second line 52 (second low temperature line 52a) to each local cooling device 4.

In addition, the heat medium R discharged from each of the local cooling devices 4A to 4D merges with the second high temperature line 52b of the second line 52.

In this way, the cooling system 1 can appropriately and efficiently cool each load device L by using the plurality of local cooling devices 4. In this way, in a case where the amount of heat generated differs for each load device L, it is possible to suppress the occurrence of overcooling in some load devices L or the occurrence of insufficient cooling in some load devices L.

### OTHER EMBODIMENTS

The embodiments have been described in detail above with reference to the drawings. However, the specific configuration is not limited to the above description, and various design changes and the like can be made. That is, in other embodiments, the procedures of the above-described processes may be changed as appropriate. In addition, some of the processes may be executed in parallel.

### APPENDIX

The cooling system described in the above-described embodiment is understood as follows, for example.

(1) According to a first aspect, a cooling system 1 includes a cooling device 2 that cools a heat medium R, air conditioning means 3 supplied with the heat medium R to cool a room in which a load device L is installed, a local cooling device 4 supplied with the heat medium R to cool the load device L, and a heat medium loop 5 that includes a first line 51 through which the heat medium R is circulated from the cooling device 2 via the air conditioning means 3, and a second line 52 that branches from the first line 51 and through which the heat medium R is circulated via the local cooling device 4. The first line 51 has a smaller pressure loss than the second line 52.

As described above, normally, the heat generating body of the load device L has a higher temperature than the indoor temperature. Therefore, even in a case where the heat medium R after being heat-exchanged by the heat exchanger 31 of the air conditioner 3A is reused, the local cooling device 4 can sufficiently absorb heat from the heat generating body of the load device L. For this reason, the heat medium R used in the air conditioner 3A is further used in the local cooling device 4 on the downstream side. In this manner, it is not necessary to provide a plurality of cooling devices 2 for each of the air conditioner 3A and the local cooling device 4, and the heat medium R cooled by one cooling device 2 can be used to the maximum extent. That is, both the room and the load device L can be cooled with a simple configuration in which only one cooling device 2 is installed, and the power consumption in the entire cooling system 1 can be reduced. Further, the flow rate of the heat medium R bypassing from the first line 51 to the second line 52 can be adjusted by adjusting the difference in pressure loss by adjusting a difference in the diameter of the pipe used in the first line 51 and the second line 52 according to the number of load devices L, the load (the amount of heat generated), or the like. That is, the cooling system 1 has a simple configuration in which the first line 51 and the second line 52 having different pressure losses are provided, and is capable of adjusting the flow rate and cooling capacity of the heat medium R supplied from one cooling device 2 to the air conditioner 3A and the local cooling device 4.

(2) According to a second aspect, in the cooling system 1 according to the first aspect, the first line 51 is provided with an adjustment valve 54 that, as an opening degree decreases, increases a ratio of a flow rate of the heat medium R that is branched to and flows through the second line 52 to a flow rate of the heat medium R that flows without being branched to the second line 52.

In this way, the cooling system 1 can adjust the ratio of the heat medium R flowing to the second line 52 to the total amount of the heat medium R by increasing or decreasing the opening degree of the adjustment valve 54, and can adjust the cooling capacities of the air conditioning means 3 and the local cooling device 4.

(3) According to a third aspect, in the cooling system 1 according to the second aspect, the cooling system 1 further includes an air conditioning load acquisition unit 601 that acquires an air conditioning load of the air conditioning means 3 based on a temperature in the room, a cooling load acquisition unit 602 that acquires a cooling load of the local cooling device 4 based on a temperature of the load device L or a temperature of the second line 52, and a control unit 603 that controls an opening degree of the adjustment valve 54 based on the air conditioning load and the cooling load.

In this way, the cooling system 1 can appropriately adjust the flow rate of the heat medium R bypassing to the second line 52 according to the air conditioning load required for cooling the room by the air conditioner 3A or the cooling load required for cooling the load device L by the local cooling device 4.

(4) According to a fourth aspect, in the cooling system 1 according to the third aspect, the control unit 603 reduces the opening degree of the adjustment valve 54 in a case where the air conditioning load is less than an air conditioning low load-side threshold value and the cooling load is equal to or greater than a cooling high load-side threshold value.

In this way, the cooling system 1 can increase the flow rate of the heat medium R bypassing to the second line 52 and increase the cooling capacity of the local cooling device 4.

(5) According to a fifth aspect, in the cooling system 1 according to the third or fourth aspect, the control unit 603 increases the opening degree of the adjustment valve 54 in a case where the air conditioning load is equal to or greater than an air conditioning high load-side threshold value and the cooling load is less than a cooling low load-side threshold value.

In this way, the cooling system 1 can reduce the pressure loss of the entire system and increase the cooling capacity of the air conditioner 3A.

(6) According to a sixth aspect, in the cooling system 1 according to any one of the third to fifth aspects, the first line 51 and the second line 52 are connected in parallel, and the control unit 603 closes the adjustment valve 54 to stop the supply of the heat medium R to the air conditioning means 3.

In this way, in a case where cooling of the room is not required, for example, in winter, the cooling system 1 can supply the heat medium R only to the local cooling device 4 without supplying the heat medium R to the air conditioning means 3. As a result, it is not necessary to flow the heat medium R to an unnecessary location (air conditioning means 3), and thus the power consumption of the pump 53 or the like can be reduced. In addition, the power consumption can be further reduced by stopping the air conditioner fan 32. In addition, since the heat medium R that is cooled by the cooling device 2 is directly supplied to the local cooling device 4, the cooling capacity of the local cooling device 4 can be greatly improved.

(7) According to a seventh aspect, in the cooling system 1 according to any one of the third to sixth aspects, the air conditioning means 3 is an air conditioner 3A having an air conditioner fan 32, and the control unit 603 stops the air conditioner fan 32 in a case where the air conditioning load is less than the air conditioning low load-side threshold value and the cooling load is equal to or greater than the cooling high load-side threshold value.

In this way, the cooling system 1 can minimize the consumption of power in the air conditioner 3A in a case where cooling of the room is not required.

(8) According to an eighth aspect, in the cooling system 1 according to any one of the first to sixth aspects, the air conditioning means 3 is a finned tube 3B.

For example, in a facility provided in a high latitude region, an indoor temperature may be low throughout the year. As a result, it is assumed that a device having high cooling capacity, such as the air conditioner 3A, is not required. In this case, by replacing the air conditioning means 3 from the air conditioner 3A with the finned tube 3B, the power consumption of the cooling system 1 can be significantly reduced while ensuring the cooling capacity of the room with the flow rate of the heat medium R flowing through the finned tube 3B.

(9) According to a ninth aspect, in the cooling system 1 according to any one of the first to eighth aspects, a plurality of the local cooling devices 4 are provided corresponding to a plurality of the load devices L.

In this way, the cooling system 1 can appropriately and efficiently cool each load device L by using the plurality of local cooling devices 4. In this way, in a case where the amount of heat generated differs for each load device L, it is possible to suppress the occurrence of overcooling in some load devices L or the occurrence of insufficient cooling in some load devices L.

### Industrial Applicability

According to the above aspect, both the room and the load device can be cooled with a simple configuration, and the power consumption can be reduced.

### REFERENCE SIGNS LIST

1: cooling system
2: cooling device
21: fan
3: air conditioning means
3A: air conditioner
31: heat exchanger
32: air conditioner fan
3B: finned tube
4, 4A to 4D: local cooling device
41: local cooling loop
42, 42A to 42D: local cooling valve
5: heat medium loop
51: first line
51a: first low temperature line
51b: first high temperature line
52: second line
52a: second low temperature line
52b: second high temperature line
53: pump
54: adjustment valve
55: first valve
56: second valve
6: control device
60: processor
61: memory
62: storage
63: communication interface (I/F)
601: air conditioning load acquisition unit
602: cooling load acquisition unit
603: control unit
10: power supply
L, L1 to L4: load device
R: heat medium
T1: first temperature sensor
T2: second temperature sensor

1. A cooling system comprising:
a cooling device that cools a heat medium;
air conditioning means supplied with the heat medium to cool a room in which a load device is installed;
a local cooling device supplied with the heat medium to cool the load device; and
a heat medium loop that includes a first line through which the heat medium is circulated from the cooling device via the air conditioning means, and a second line that branches from the first line and through which the heat medium is circulated via the local cooling device,
wherein the first line has a smaller pressure loss than the second line,
wherein the first line is provided with an adjustment valve that, as an opening degree decreases, increases a ratio of a flow rate of the heat medium that is branched to and flows through the second line to a flow rate of the heat medium that flows without being branched to the second line.

2. (canceled)

3. The cooling system according to claim 1, further comprising:
an air conditioning load acquisition unit that acquires an air conditioning load of the air conditioning means based on a temperature in the room;
a cooling load acquisition unit that acquires a cooling load of the local cooling device based on a temperature of the load device or a temperature of the second line; and
a control unit that controls the opening degree of the adjustment valve based on the air conditioning load and the cooling load.

4. The cooling system according to claim 3,
wherein the control unit reduces the opening degree of the adjustment valve in a case where the air conditioning load is less than an air conditioning low load-side threshold value and the cooling load is equal to or greater than a cooling high load-side threshold value.

5. The cooling system according to claim 3,
wherein the control unit increases the opening degree of the adjustment valve in a case where the air conditioning load is equal to or greater than an air conditioning high load-side threshold value and the cooling load is less than a cooling low load-side threshold value.

6. The cooling system according to claim 3,
wherein the first line and the second line are connected in parallel, and
the control unit closes the adjustment valve to stop the supply of the heat medium to the air conditioning means.

7. The cooling system according to claim 4,
wherein the air conditioning means is an air conditioner having an air conditioner fan, and
the control unit stops the air conditioner fan in a case where the air conditioning load is less than the air conditioning low load-side threshold value and the cooling load is equal to or greater than the cooling high load-side threshold value.

8. (canceled)

9. The cooling system according to claim 1,
wherein a plurality of the local cooling devices are provided corresponding to a plurality of the load devices.
